(19) United States
(12) Patent Application Publication
(10) Pub. No.: US 2022/0214381 A1
(43) Pub. Date: Jul. 7, 2022

(54) MICROELECTRONIC TEST INTERFACE SUBSTRATES, DEVICES, AND METHODS OF MOUNTING ON A PRINTED CIRCUIT TEST LOAD BOARD

(71) Applicant: Raymond Won Bae, Danville, CA (US)

(72) Inventor: Raymond Won Bae, Danville, CA (US)

(21) Appl. No.: 17/514,106

(22) Filed: Oct. 29, 2021

Related U.S. Application Data
(60) Provisional application No. 63/199,490, filed on Jan. 2, 2021.

(51) Int. Cl. G01R 3/00; G01R 1/073; H01L 23/00

(52) U.S. Cl. CPC G01R 3/00; H01L 2224/81815; H01L 24/81; G01R 1/07307

(57) ABSTRACT

An embodiment of the present invention provides a method of manufacture thereof controlled alloy amount, height, quality, and optical alignment joining the microelectronic test interface substrate to the printed circuit test load board and real time alloy quality inspection of the test load board system. An embodiment of the system platform comprising: a microelectronic test interface substrate and a printed circuit test load board, such as probe card system and device test load board system.

### TECHNICAL FIELD

An embodiment of the present invention relates generally to microelectronic test substrate reflow soldering assembly.

### BACKGROUND

Reflow soldering is predominant method of connecting the microelectronic test interface substrate on the printed circuit test load board. As semiconductor fabrication technology advances continue to be implemented; the critical dimension or spacing between connecting pads and pitch between the test interface substrate and the load boards continues to shrink; the number of the test interface substrate layer counts are increasing; the number of BGA (Ball Grid Array) or LGA (Line Grid Array) solder joining contact number are increasing with decrease in pad size and pitch; the material types of the test substrate are changing. For example, these cause the unpredictable soldering assembly quality issues between the microelectronic test interface substrate and the printed circuit test load board.

A technology bottleneck occurs that is associated with existing solder reflow assembly techniques that do not readily support such changes in the microelectronic test substrate interface system structures.

As users become more empowered with the growth of computing devices, new and old paradigms begin to take advantage of this new device space. There are many technological solutions to take advantage of this new device capability and device miniaturization. However, reliable assembly of the microelectronic test interface substrate and faster delivery of the complete test load board system for new wafer chips and devices testing has become a concern for manufactures.

Thus, a need still remains for a more reliable method of solder and/or other conductive metal joining between the microelectronic test interface substrate and the printed circuit test load board system. In view of the ever-increasing high-speed applications and performance, better commercial competitive pressures, along with growing consumer expectations and the diminishing opportunities for meaningful product differentiation in the marketplace, it is increasingly critical that answers be found to these problems. Additionally, the need to provide manufacturing capabilities of inspection of solder and/or other conductive metal joints between the microelectronic test interface substrate and the printed circuit test load board. This improves efficiencies, performance and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

An embodiment of the present invention provides a microelectronic test interface system including: a microelectronic test interface substrate and a printed circuit test load board, such as probe card system and device test load board system.

An embodiment of the present invention provides a method of manufacture thereof controlled solder and/or other conductive metal amount joining the microelectronic test interface substrate to the printed circuit test load board and real time solder and/or other conductive metal quality inspection of the test load board system.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a schematic side view of a probe card system in an embodiment of the present invention microelectronics test interface substrate and printed circuit test load board system 810 is integrated.

FIG. 2 schematic view of an embodiment of microelectronic test interface substrate system 700 bottom view (aka BGA, LGA or PCB side) and the bottom view (aka substrate, chip, or device side) of a printed circuit load board system 610.

FIG. 3 is a schematic cross-sectional side view of an embodiment of microelectronic test load board system 810 with the solder joint system 900 connecting the microelectronic test interface substrate 700 and the printed circuit test load board 610.

FIG. 4 is a schematic sectional bottom view of an embodiment of microelectronic test interface substrate system 700 of dotted section 715 in FIG. 2. and the solder paste and/or other conductive metal stencil 410.

FIG. 5 is a schematic cross-sectional close side view of an embodiment of microelectronic test interface substrate system one process of forming solder bumps by applying the solder paste on solder joining pad 720 of the microelectronic test interface substrate system 700.

FIG. 6 is a schematic cross-sectional close side view of an embodiment of microelectronic test interface substrate system other processes of forming solder and/or other conductive metal bumps by applying the commercially available solder and/or other conductive metal balls on solder joining pad 720 of the microelectronic test interface substrate system 700.

FIG. 7 is a schematic cross-sectional close side view of an embodiment of the platform system D in FIG. 5 forming a solder bump on the microelectronic test interface substrate BGA pad system 440 using top 680 and bottom 690 programmable heating apparatus.

FIG. 8 is a schematic cross-sectional close side view of an embodiment of the microelectronic test interface substrate system 700 after the solder and/or other conductive metal bump 950 formation.

FIG. 9 is a schematic cross-sectional close side view of an embodiment of the printed circuit test load board system process of applying the solder paste on solder joining pad 620 of the load board system 610.

FIG. 10 is a schematic cross-sectional close side view of an embodiment of the optically aligning and placing the test interface substrate system 700 on the pasted load board system 680.

FIG. 11 is a schematic cross-sectional close top optically aligned view of an embodiment of the test interface substrate system 700 place on the test load board system 680 forming a system 820.

FIG. 12 is a schematic cross-sectional close side view of an embodiment of FIG. 10 permanently joining the test interface substrate and the load board system 820 using top 680 and bottom 690 programmable heating apparatus.

FIG. 13 is a schematic close bottom view a test load board system 810 of FIG. 1

FIG. 14 is a schematic cross-sectional close side view of an embodiment of FIG. 12 crossed thru line 160-160 permanently joining the test interface substrate 700 and the load board 610 to be a complete integral part of the system 800 in FIG. 1.

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of an embodiment of the present invention.

In the following description, numerous specific details are given to provide a thorough understanding of the invention. However, it will be apparent that the invention may be practiced without these specific details. In order to avoid obscuring an embodiment of the present invention, some well-known circuits, system configurations, and process steps are not disclosed in detail.

The drawings showing embodiments of the system are semi-diagrammatic, and not to scale and, particularly, some of the dimensions are for the clarity of presentation and are shown exaggerated in the drawing figures. Similarly, although the views in the drawings for ease of description generally show similar orientations, this depiction in the figures is arbitrary for the most part. Generally, the invention can be operated in any orientation.

In this embodiment, the microelectronic test interface substrate and the printed circuit load board are used to describe this invention method manufacture thereof. However, it can be applied to any microelectronic test boards requiring the use of the microelectronic test interface substrate.

The designation and usage of the term first, second, third, etc. is for convenience and clarity and is not meant limit a particular order. The steps or processes described can be performed in any order to implement the claimed subject matter.

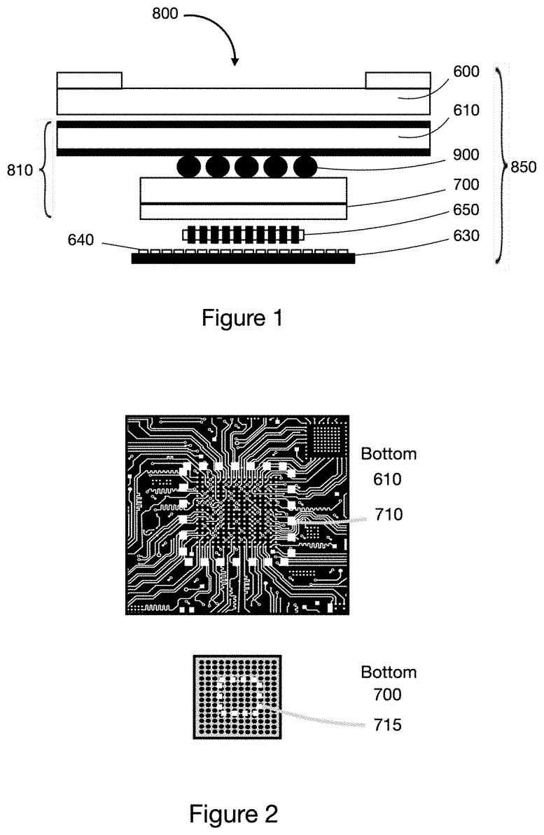

Referring now to FIG. 1, therein is shown an embodiment of microelectronic test interface substrate system schematic side view of a probe card system 800 and an embodiment of the present invention 810 is integrated. The system 800 is a system for providing interconnection between different devices. For example, the system 800 can be a component in a wafer testing system 850 or a substrate in an integrated circuit packaging system. As an example, the wafer testing system 850 can include a mechanical stiffener 600, a printed circuit load board 610, a test interface substrate platform 700 solder joint 900 to a printed circuit load board 610 and a probe head 650. The mechanical stiffener 600, the printed circuit board 610, the test interface substrate platform 700, and the probe head 650 are components for a system to test a semiconductor wafer 630. The semiconductor wafer 630 can include a die 640 with electronic components, such as circuits, integrated circuits, logic, integrated logic, or a combination thereof fabricated thereon.

Referring now to FIG. 2, therein is shown an embodiment of microelectronic test interface substrate system bottom view 700 of FIG. 1. The bottom conductor pads of the microelectronic test interface substate are interconnecting bottom of the printed circuit test load board 610. The top side of the microelectronic test interface substrates are interconnecting to the probe head 650 of FIG. 1 for wafer chip 630 of FIG. 1 and other logic and integrated devices to be tested. The top side of the printed circuit test load boards are supported by the mechanical stiffener system 600 and connected to the automated test equipment.

The microelectronic test interface substrate platform system 700 is a structure for providing interconnection between two devices. The system 700 has started to incorporate into the probe card system 800 when the semiconductor device is getting more complex in terms of design and functionality that required more testing points and finer test points. For example, the platform system 700 can be a space transformer, a device interface structure for a multi-die package, or a combination thereof. The platform system 700 can provide electrical and functional connectivity between semiconductor wafer 630, the die 640, or a combination thereof, and the rest of the system 800.

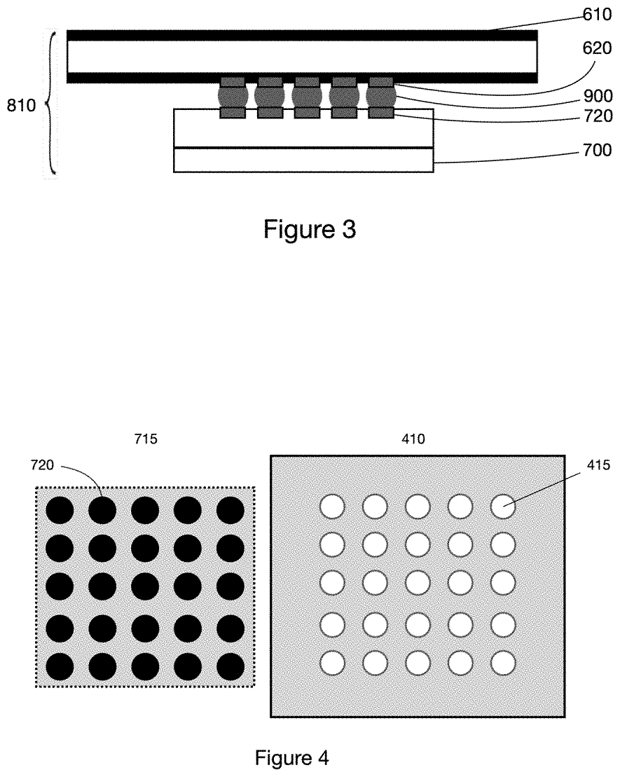

Referring now to FIG. 3, therein is shown an embodiment of test load board system cross-sectional side view of 810; a microelectronic test interface substrate system 700 connecting via solder joining system 900 with the printed circuit test load board system 610. For illustrative purpose, the microelectronic test interface substrate and the printed circuit test load board are depicted having a similar shape from the side view, although it is understood that the system 700 and 810 can have a different size, shape, and thickness. Moreover, design complexity for the testing makes the system 700 and system 610 bigger and thicker and the solder jointing system 900 height or thickness is in micron range. Hence it makes the current method of solder joining reflow system impossible to control the outcome of the reliable system integration.

The consistent thickness and solder and/or other conductive metal amount among all solder joint system 900 between the microelectronic test interface substrate bottom BGA (Ball Grid Array) or LGA (Line Grid Array) system 720 and the printed circuit test load board system 610 is extremely important for the test signal integrity performance. Therefore, consistent density and size of solder and/or other conductive metal joints provides the more consistent performance in the solder joint system 900.

Referring now to FIG. 4, therein is shown an embodiment of microelectronic test interface substrate system top view of the sectional BGA or LGA system 715 in FIG. 2 and the stencil platform 410. The microelectronic test interface substrate bottom side of BGA or LGA system 700 can have in thousands of 720 pads and the pad-to-pad pitch in hundredth micron range. These numbers of system 720 pads in the microelectronic interface substate correspond to the same number and alignment to the printed circuit test load board system 610 for the solder and/or other conductive metal joint integration. The stencil platform 410 is made with expose the open holes 415 to match the system 720 pads.

For example, the density and close proximity of fine pitch of system 720 can cause the following defects in current solder reflow manufacturing system; cold solder joints, over heated solder joints, skip solder (open), solder bridge (short), free solder ball, insufficient solder wetting, solder webbing, and the solder voids. The rework to fix defect raise the reliability concerns due to physical and electrical damage to the microelectronic test interface substrate system.

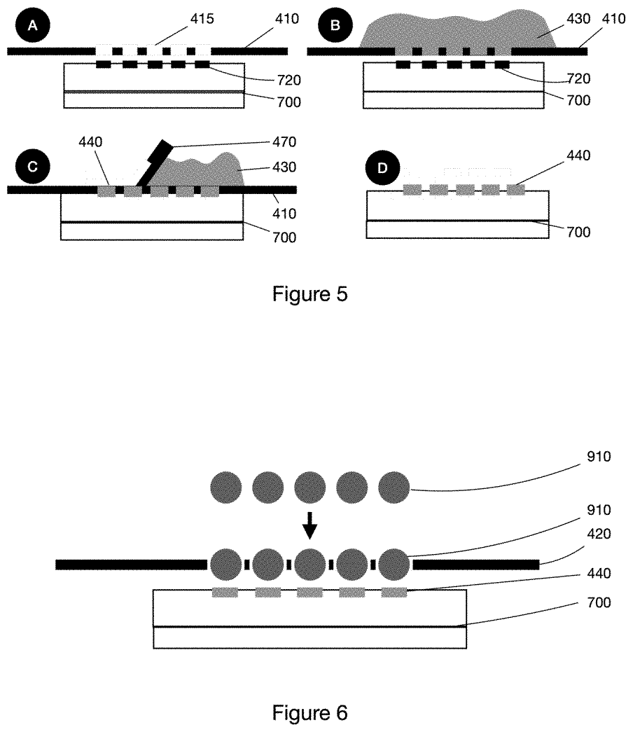

Referring now to FIG. 5 is a schematic cross-sectional close side view of an embodiment of microelectronic test interface substrate system 700 and the stencil platform system 410. This is one of methods of applying the solder and/or other conductive metal bump distribution on the microelectronic test interface substrate system 700 using the stencil platform system. The illustration A, B, C and D show the sequence of applying the solder paste on the microelectronic test substrate system 700: A—the stencil system 410 is aligned with the microelectronic test substrate system 700 BGA pad 720; B—solder paste system 430 is applied on the stencil system 410; C—using squeeze system 470 to remove access solder paste system 430 leaving exact amount of the solder paste on system 720 to from system 440 which is the combination of the system 720 and 430; D—showing the removal of the stencil system and leaving the system 440 on the microelectronic test interface substrate system 700.

At this stage after the removal of the stencil system, the system 440 can be inspected. This process illustrates the even distribution, amount and alignment of the solder paste on the system 440. For example, evenly well positioned distribution amount of the solder paste is critical part of the reliable performance of the test board system. This prevents the potential solder overflow and underflow which cause the short and open connection problem.

FIG. 6 is a schematic cross-sectional close side view of an embodiment of microelectronic test interface substrate system other processes of forming solder and/or other conductive metal bumps by applying the commercially available solder and/or other conductive metal balls 910 on solder joining pad 720 of the microelectronic test interface substrate system 700. The selection of the commercially available solder or other conductive metal balls 910 is based on the solder and/or other conductive metal bump size requirement. The selection of solder and/or other conductive metal ball stencil system 420 is also based the spherical size of the solder and/or other conductive metal balls.

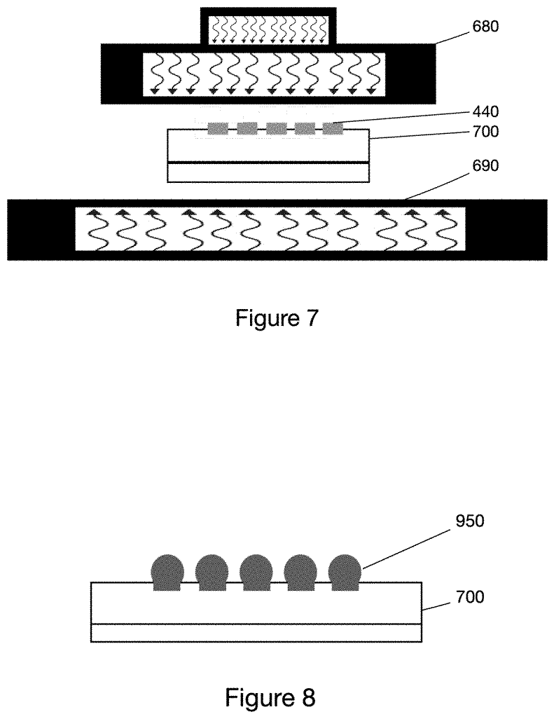

Referring now to FIG. 7 is a schematic cross-sectional close side view of an embodiment of the platform system D in FIG. 5 and FIG. 6 forming a solder and/or other conductive metal bump on the microelectronic test interface substrate BGA pad system 440 using top 680 and bottom 690 programmable heating system to provide the gradient temperature profiles and even thermal distribution to form solder and/or other conductive metal pumps on the microelectronic test interface substrate BGA pad system 440. The even thermal distribution is also proven to provide the less void in the solder and/or other conductive metal pumps.

For illustrate purpose, it is important to understand the current method of solder reflow to assembly the system 810 in FIG. 3: First, the solder paste is applied to the BGA pads 620 of the printed circuit test load board system 610; second, the microelectronic test interface substate is placed using the alignment keys on the BGA pads 620 of the system 610; third, they are placed in the multiple temperature reflow system. Hence the warpage, thickness, size, and the density of both microelectronic test interface substrate 700 and printed circuit test load board 610 cause the different solder joint quality issues during the reflow process.

Unlike the current method of solder reflow system, the method of FIG. 5 and FIG. 6 are good illustration of open solder application and soldering process to prevent the solder quality issues. Hence it is a selective open soldering process of the microelectronic test interface substrate to quality control process allowing the inspection of the solder and/or other conductive metal pumps prior to joining to the printed circuit test load board system 610.

Referring now to FIG. 8 is a schematic cross-sectional close side view of an embodiment of the microelectronic test interface substrate system 700 after the solder and/or other conductive metal bump 950 formation. The visual inspection of the bump heights, size and alignment at this point prevents the many potential soldering issues when the microelectronic test interface substate system 700 is aligned and joined to the printed circuited test load board system 610.

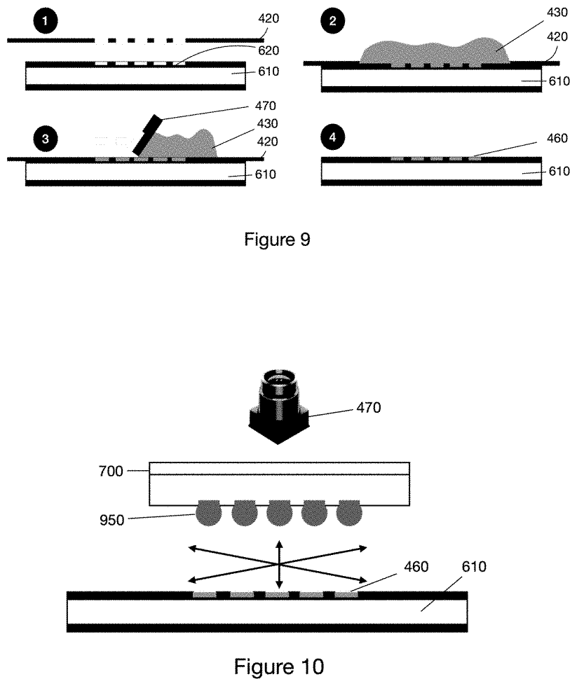

Referring now to FIG. 9 is a schematic cross-sectional close side view of an embodiment of the printed circuit test load board system 610 process of applying the solder paste on solder joining pad 620. The proper solder paste placement can be inspected. Hence the quality solder and/or other conductive metal bumps are already inspected and formed on the microelectronic test interface substrate system 700 as in FIG. 8, the solder paste application of the printed circuit load board system 610 provides the better solder wetting and prevents opens in the final test load board system 810 in FIG. 3.

For illustrate purpose, the stencil system 420 thickness determines the amount of the solder paste on the BGA pad system 620 of the printed circuit test board system 610. The use of the different thickness of the stencil system 420 reduces the potential solder open and wetting issues due to the warpage of the both the microelectronic test interface substrate system 700 and the printed circuit test load board 610.

Referring now to FIG. 10 is a schematic cross-sectional close side view of an embodiment of the optically placing the test interface substrate system 700 on the pasted load board system 680. Unlike current method of placing the microelectronic test interface substrate system 700, the real time optical camera view alignment of both BGA arrays system 950 of the microelectronic test interface substrate system 700 and BGA array system 460 of the printed circuit test load board system 610 provide placement accuracy based on the actual pad to pad alignment.

For example, FIG. 10 camera optical system 470 alignment process offers the advantages of: Maximizing the fine pitch BGA placement; reducing the displacement error due to X and Y coordinate variation between the system 700 and 610; and prevent the solder paste spattering.

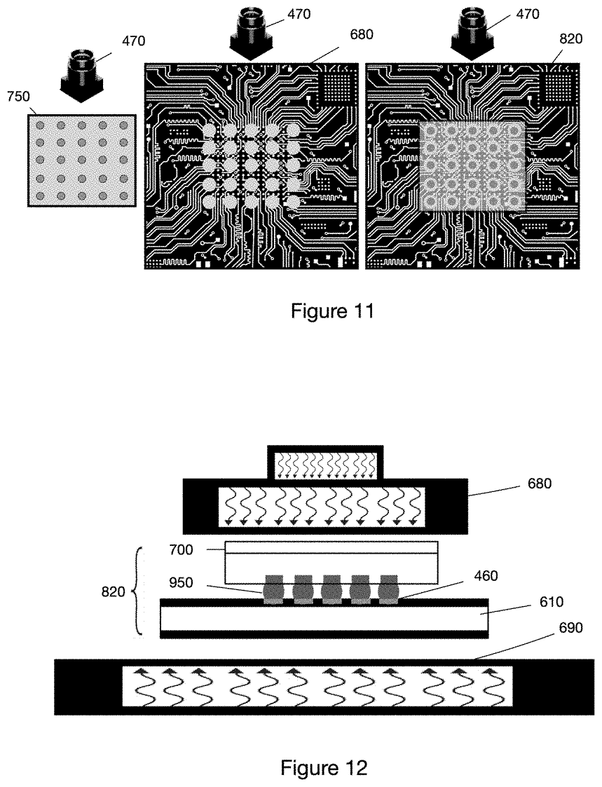

Referring now to FIG. 11 is a schematic cross-sectional close top optically aligned view of an embodiment of the test interface substrate system 700 place on the test load board system 680 forming a system 820. For example, of this embodiment allow the visual inspection of the alignment, solder distribution and contacts of the solder joints. The image capture is also beneficial for the quality comparison of before and after the solder joint assembly. Referring now to FIG. 12 is a schematic cross-sectional close side view of an embodiment of FIG. 10 permanently joining the test interface substrate and the load board system 820 using top 680 and bottom 690 heating apparatus. Hence the microelectronic test interface substrate system 700 is already assembled with solder and/or other conductive metal bumps and inspected, FIG. 12 process provides the less thermal stress and controllability on the solder joining assembly process. Top 680 and bottom 690 programmable heating system to provide the gradient temperature profiles and even thermal distribution to solder paste melt and the formation of the successful solder joint system 900.

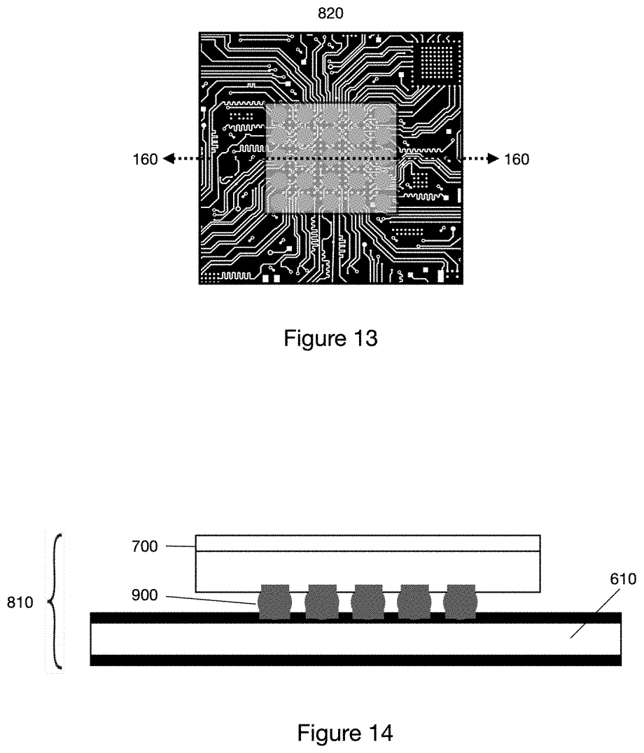

Referring now to FIG. 13 is a schematic close bottom view of an embodiment of a test load board system 810 of FIG. 1. The X-ray image of the solder joint system 900 and the optical image from FIG. 11 comparison is good quality assurance to minimize the soldering defects during the actual usage of the probe card system 800 during the testing of the semiconductor chips and devices.

Referring now to FIG. 14 is a schematic cross-sectional close side view of an embodiment of FIG. 13 crossed thru line 160-160 permanently joining the test interface substrate 700 and the load board 610 to be a complete integral part of the system 800 in FIG. 1. The thickness of the test load board system 820 is important as an integral part of the test probe card system 800.

For illustrate purposes, the controlled solder and/or other conductive metal bump height and size on the microelectronic test interface substrate system 700, the controlled solder paste amount application on the printed circuit test board 610, accurate alignment placement of systems 700 and 610 delivers the consistent thickness of the test load board system 820 for the better and efficient testing performance.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level.

While the invention has been described in conjunction with a specific best mode, it is to be understood that many alternatives, modifications, and variations will be apparent to those skilled in the art considering a foregoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. Probe card system comprising: A, a microelectronic test interface substrate comprising base carrier, dielectric, conductor traces, conductor vias connecting layers. B, a printed circuit test load board comprising dielectric, conductor traces, conductor vias connecting layers. C, a solder and/or other conductive metal joint between a microelectronic test interface substrate and a printed circuit test load board.

2. Probe card system of claim 1, wherein the via conductor provide an interlocking or connecting function with the top or bottom layer conductor.

3. Probe card system of claim 1, wherein the microelectronic test interface substrate is an organic printed circuit board laminate, a ceramic, a polyimide, and another polymer material in construction of single, multi-layers or hybrid layers.

4. Probe card system of claim 1, wherein the printed circuit test load board is an organic printed circuit board laminate, a ceramic, a polyimide, and another polymer material in construction of single, multi-layers or hybrid layers.

5. Probe card system of claim 1, wherein the solder and/or other conductive metal bump is made with any combination of solder paste, solder and/or other conductive metal balls, liquid flux, and solid flux material in construction.

6. The method of claim 1, wherein the solder and/or other conductive metal join of a microelectronic test interface substrate and a printed circuit test load board is made with any combination of solder paste, solder and/or other conductive metal balls, liquid flux, and solid flux material in construction.

7. A method of manufacturing solder joining the microelectronic test interface substrate and the printed circuit test load system comprising: A, providing a microelectronic test interface substrate forming a controlled solder and/or other conductive metal bump size and height on BGA pads, inspection of solder and/or other conductive metal bump and measuring of XY coordinates. B, providing a printed circuit test load board forming a controlled layer of paste on the BGA pads, inspection of solder pastes and measuring of XY Coordinates.

8. The method of claim 7, wherein the microelectronic test interface substrate is an organic printed circuit board laminate, a ceramic, a polyimide, and another polymer material in construction of single, multi-layers or hybrid layers.

9. The method of claim 7, wherein the printed circuit test load board is an organic printed circuit board laminate, a ceramic, a polyimide, and another polymer material in construction of single, multi-layers or hybrid layers.

10. The method of claim 7, wherein the solder and/or other conductive metal bump is made with any combination of solder paste, solder and/or other conductive metal balls, liquid flux, and solid flux material in construction.

11. The method of claim 7, wherein the solder join of a microelectronic test interface substrate and a printed circuit test load board is made with any combination of solder paste, solder and/or other conductive metal balls, liquid flux, and solid flux material in construction.

12. The method of claim 7, wherein the inspection of solder and/or other conductive metal bump is visual or using inspection system.

13. The method of claim 7, wherein the inspection of solder paste is visual or using inspection system.

14. The method of claim 7, wherein the measuring XY coordinate is manual or using measuring system.

15. The method of forming an overlayed structure by placing a microelectronic test interface substrate and a printed circuit test load board using an optical camera alignment system comprising: A, a microelectronic test interface substrate comprising base carrier, dielectric, conductor traces, conductor vias connecting layers. B, a printed circuit test load board comprising dielectric, conductor traces, conductor vias connecting layers. C, an optical camera alignment system showing the surface views of both microelectronic test interface substrate and printed circuit test load board.

16. The method of claim 15, wherein the microelectronic test interface substrate is an organic printed circuit board laminate, a ceramic, a polyimide, and another polymer material in construction of single, multi-layers or hybrid layers.

17. The method of claim 15, wherein the printed circuit test load board is an organic printed circuit board laminate, a ceramic, a polyimide, and another polymer material in construction of single, multi-layers or hybrid layers.

18. The method of claim 15, wherein the solder and/or other conductive metal bump is made with any combination of solder paste, solder and/or other conductive metal balls, liquid flux, and solid flux material in construction.

19. The method of claim 15, wherein the solder join of a microelectronic test interface substrate and a printed circuit test load board is made with any combination of solder paste, solder and/or other conductive metal balls, liquid flux, and solid flux material in construction.

20. The method of claim 15, wherein an optical camera alignment system is manual or computer aided system.

21. The method of Joining a microelectronic test interface substrate and a printed circuit test load board using programmable temperature control top and bottom heating system comprising: A, a microelectronic test interface substrate comprising base carrier, dielectric, conductor traces, conductor vias connecting layers. B, a printed circuit test load board comprising dielectric, conductor traces, conductor vias connecting layers. C, a programmable top and bottom temperature profile heating system.

22. The method of claim 21, wherein the microelectronic test interface substrate is an organic printed circuit board laminate, a ceramic, a polyimide, and another polymer material in construction of single, multi-layers or hybrid layers.

23. The method of claim 21, wherein the printed circuit test load board is an organic printed circuit board laminate, a ceramic, a polyimide, and another polymer material in construction of single, multi-layers or hybrid layers.

24. The method of claim 21, wherein the solder and/or other conductive metal bump is made with any combination of solder paste, solder and/or other conductive metal balls, liquid flux, and solid flux material in construction.

25. The method of claim 21, wherein the solder join of a microelectronic test interface substrate and a printed circuit test load board is made with any combination of solder paste, solder and/or other conductive metal balls, liquid flux, and solid flux material in construction.

26. The method of claim 21, a programmable top and bottom temperature controlled top and bottom heating system is manual or computer aided system.
